(19) United States
(12) Patent Application Publication
(10) Pub. No.: US 2023/0029955 A1
(43) Pub. Date: Feb. 2, 2023

(54) TRANSISTOR STRUCTURE HAVING REDUCED CONTACT RESISTANCE AND METHODS OF FORMING THE SAME

(71) Applicant: Taiwan Semiconductor Manufacturing Company Limited, Hsinchu (TW)

(72) Inventors: Neil Quinn Murray, Hsinchu (TW); Mauricio Manfrini, Zhubei City (TW)

(21) Appl. No.: 17/738,169

(22) Filed: May 6, 2022

Related U.S. Application Data
(60) Provisional application No. 63/227,075, filed on Jul. 29, 2021.

(51) Int. Cl. H01L 29/786; H01L 29/66; H01L 29/51; H01L 29/45

(52) U.S. Cl. CPC H01L 29/78669; H01L 29/66765; H01L 29/517; H01L 29/458; H01L 29/7869; H01L 29/66969

(57) ABSTRACT

Disclosed transistor structures include a gate electrode, an active layer, a gate dielectric layer separating the active layer from the gate electrode, a source electrode, a drain electrode, and a hydrogen-rich material layer separating the source electrode and the drain electrode from the active layer. The presence of hydrogen in the hydrogen-rich material layer may act to reduce contact resistances and Schottky barriers between the source electrode and the active layer, and between the drain electrode and the active layer, thus leading to improved device performance. The disclosed transistor structures may be formed in a BEOL process and may be incorporated with other BEOL circuit components. As such, the disclosed transistor structures may include materials that may be processed at low temperatures and thus, may not damage previously fabricated devices.

### RELATED APPLICATION

This application claims priority to U.S. Provisional Patent Application No. 63/227,075 entitled “Back-End-Of-Line (BEOL) Thin Film Transistor (TFT) having reduced contact resistance through hydrogen-storage in Source/Drain (S/D) metal module and Methods of forming the same” filed on Jul. 29, 2021, the entire contents of which are hereby incorporated by reference for all purposes.

### BACKGROUND

The semiconductor industry has grown due to continuous improvements in integration density of various electronic components (e.g., transistors, diodes, resistors, inductors, capacitors, etc.). For the most part, these improvements in integration density have come from successive reductions in minimum feature size, which allow more components to be integrated into a given area. In this regard, individual transistors, interconnects, and related structures have become increasingly smaller and there is an ongoing need to develop new materials, processes, and designs of semiconductor devices and interconnects to allow further progress.

Thin-film transistors made of oxide semiconductors are an attractive option for back-end-of-line (BEOL) integration since thin-film transistors may be processed at low temperatures and thus, may not damage previously fabricated devices. For example, the fabrication conditions and techniques may not damage previously fabricated front-end-of-line (FEOL) and middle end-of-line (MEOL) devices. Circuits based on thin-film transistor devices may further include other components that may be fabricated in a BEOL process, such as capacitors, inductors, resistors, and integrated passive devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a first exemplary structure after formation of complementary metal-oxide-semiconductor (CMOS) transistors, first metal interconnect structures formed in lower-level dielectric material layers, and an isolation dielectric layer, according to various embodiments.

FIG. 2 is a vertical cross-sectional view of an intermediate structure that may be used in the formation of a transistor structure, according to various embodiments.

FIG. 3 is a vertical cross-sectional view of a further intermediate structure that may be used in the formation of a transistor structure, according to various embodiments.

FIG. 4 is a vertical cross-sectional view of a further intermediate structure that may be used in the formation of a transistor structure, according to various embodiments.

FIG. 5 is a vertical cross-sectional view of a further intermediate structure that may be used in the formation of a transistor structure, according to various embodiments.

FIG. 6 is a vertical cross-sectional view of a further intermediate structure that may be used in the formation of a transistor structure, according to various embodiments.

FIG. 7 is a vertical cross-sectional view of a further intermediate structure that may be used in the formation of a transistor structure, according to various embodiments.

FIG. 8 is a vertical cross-sectional view of a further intermediate structure that may be used in the formation of a transistor structure, according to various embodiments.

FIG. 9 is a vertical cross-sectional view of a further intermediate structure that may be used in the formation of a transistor structure, according to various embodiments.

FIG. 10 is a vertical cross-sectional view of a further intermediate structure that may be used in the formation of a transistor structure, according to various embodiments.

FIG. 11 is a vertical cross-sectional view of a transistor structure, according to various embodiments.

FIG. 12 is a vertical cross-sectional view of a further intermediate structure that may be used in the formation of a transistor structure, according to various embodiments.

FIG. 13 is a vertical cross-sectional view of a further intermediate structure that may be used in the formation of a transistor structure, according to various embodiments.

FIG. 14 is a vertical cross-sectional view of a further transistor structure, according to various embodiments.

FIG. 15 is a vertical cross-sectional view of a further transistor structure, according to various embodiments.

FIG. 16 is a vertical cross-sectional view of a further transistor structure, according to various embodiments.

FIG. 17 is a vertical cross-sectional view of a further transistor structure, according to various embodiments.

FIG. 18 is a flowchart illustrating operations of a method of manufacturing a transistor structure, according to various embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

According to various embodiments of this disclosure, a transistor structure (e.g., a thin-film transistor) is provided that may be formed in a BEOL process and may be incorporated with other BEOL circuit components such as capacitors, inductors, resistors, and integrated passive devices. As such, the disclosed transistor structure may include materials that may be processed at low temperatures and thus, may not damage previously fabricated devices (e.g., FEOL and MEOL devices).

Existing BEOL compatible thin-film transistors often suffer degradation of the on-current due to high Schottky barrier heights respectively between the source electrode the active region, and between drain electrode and the active region. Metal contacts for source and drain electrodes of existing systems typically include pure metals (e.g., W, Cu, etc.) or materials deposited using PVD (TiN, W, etc.). Both such materials tend to have low amounts of hydrogen in the material and therefore often result in a high contact resistance and degraded device performance. Hydrogen is known to act has a donor-like dopant in oxide semiconductor materials used in thin-film transistors. By using a metal compound rich in hydrogen the source and drain region can be selectively doped to have high carrier concentration which may reduce the Schottky barrier height and the contact resistance and thereby improve device performance.

Various embodiment transistor structures include a gate electrode, an active layer, a gate dielectric layer separating the active layer from the gate electrode, a source electrode, a drain electrode, and a hydrogen-rich material layer separating the source electrode and the drain electrode from the active layer.

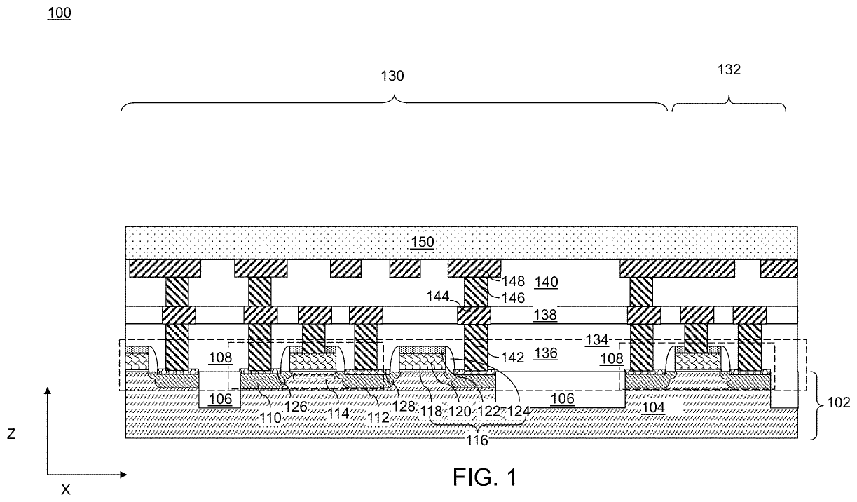

FIG. 1 illustrates a semiconductor structure 100, according to various embodiments. The semiconductor structure 100 includes a substrate 102, which may be a semiconductor substrate such as a commercially available silicon substrate. The substrate 102 may include a semiconductor material layer 104 or at least at an upper portion thereof. The semiconductor material layer 104 may be a surface portion of a bulk semiconductor substrate, or may be a top semiconductor layer of a semiconductor-on-insulator (SOI) substrate. In one embodiment, the semiconductor material layer 104 includes a single crystalline semiconductor material such as single crystalline silicon. In one embodiment, the substrate 102 may include a single crystalline silicon substrate including a single crystalline silicon material.

Shallow trench isolation structures 106 including a dielectric material such as silicon oxide may be formed in an upper portion of the semiconductor material layer 104. Suitably doped semiconductor wells, such as p-type wells and n-type wells, may be formed within each area that is laterally enclosed by a portion of the shallow trench isolation structures 106. Field effect transistors 108 may be formed over a top surface of the semiconductor material layer 104. For example, each of the field effect transistors 108 may include a source electrode 110, a drain electrode 112, a semiconductor channel 114 that includes a surface portion of the substrate 102 extending between the source electrode 110 and the drain electrode 112, and a gate structure 116. The semiconductor channel 114 may include a single crystalline semiconductor material.

Each gate structure 116 may include a gate dielectric layer 118, a gate electrode 120, a gate cap dielectric 122, and a dielectric gate spacer 124. A source-side metal-semiconductor alloy region 126 may be formed on each source electrode 110, and a drain-side metal-semiconductor alloy region 128 may be formed on each drain electrode 112. The devices formed on the top surface of the semiconductor material layer 104 may include complementary metal-oxide-semiconductor (CMOS) transistors and optionally additional semiconductor devices (such as resistors, diodes, capacitors, etc.), and are collectively referred to as CMOS circuitry 134.

The semiconductor structure 100 of FIG. 1 may include a memory array region 130 in which an array of memory cells may be subsequently formed. The first exemplary structure may further include a peripheral region 132 in which metal wiring for the array of memory devices is provided. Generally, the field effect transistors 108 in the CMOS circuitry 134 may be electrically connected to an electrode of a respective memory cell by a respective set of metal interconnect structures.

Devices (such as field effect transistors 108) in the peripheral region 132 may provide functions that operate the array of memory cells to be subsequently formed. Specifically, devices in the peripheral region may be configured to control the programming operation, the erase operation, and the sensing (read) operation of the array of memory cells. For example, the devices in the peripheral region may include a sensing circuitry and/or a programming circuitry.

One or more of the field effect transistors 108 in the CMOS circuitry 134 may include a semiconductor channel 114 that contains a portion of the semiconductor material layer 104 in the substrate 102. If the semiconductor material layer 104 includes a single crystalline semiconductor material such as single crystalline silicon, the semiconductor channel 114 of each of the field effect transistors 108 in the CMOS circuitry 134 may include a single crystalline semiconductor channel such as a single crystalline silicon channel. In one embodiment, a plurality of field effect transistors 108 in the CMOS circuitry 134 may include a respective node that is subsequently electrically connected to a node of a respective memory cell to be subsequently formed. For example, a plurality of field effect transistors 108 in the CMOS circuitry 134 may include a respective source electrode 110 or a respective drain electrode 112 that is subsequently electrically connected to a node of a respective memory cell to be subsequently formed.

In one embodiment, the CMOS circuitry 134 may include a programming control circuit configured to control gate voltages of a set of field effect transistors 108 that may be used for programming a respective memory cell (e.g., a ferroelectric memory cell) and to control gate voltages of transistors (e.g., thin-film transistors) to be subsequently formed. In this embodiment, the programming control circuit may be configured to provide a first programming pulse that programs a respective ferroelectric dielectric material layer in a selected ferroelectric memory cell into a first polarization state in which electrical polarization in the ferroelectric dielectric material layer points toward a first electrode of the selected ferroelectric memory cell, and to provide a second programming pulse that programs the ferroelectric dielectric material layer in the selected ferroelectric memory cell into a second polarization state in which the electrical polarization in the ferroelectric dielectric material layer points toward a second electrode of the selected ferroelectric memory cell.

In one embodiment, the substrate 102 may include a single crystalline silicon substrate, and the field effect transistors 108 may include a respective portion of the single crystalline silicon substrate as a semiconducting channel. As used herein, a “semiconducting” element refers to an element having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant.

According to an embodiment, the field effect transistors 108 may be subsequently electrically connected to drain electrodes and gate electrodes of access transistors including semiconducting metal oxide plates to be formed above the field effect transistors 108. In one embodiment, a subset of the field effect transistors 108 may be subsequently electrically connected to at least one of the drain electrodes and the gate electrodes. For example, the field effect transistors 108 may include first word line drivers configured to apply a first gate voltage to first word lines through a first subset of lower-level metal interconnect structures to be subsequently formed, and second word line drivers configured to apply a second gate voltage to second word lines through a second subset of the lower-level metal interconnect structures. Further, the field effect transistors 108 may include bit line drivers configured to apply a bit line bias voltage to bit lines to be subsequently formed, and sense amplifiers configured to detect electrical current that flows through the bit lines during a read operation.

Various metal interconnect structures formed within dielectric material layers may be subsequently formed over the substrate 102 and the semiconductor devices thereupon (such as field effect transistors 108). In an illustrative example, the dielectric material layers may include, for example, a first dielectric material layer 136 that may be a layer that surrounds the contact structure connected to the source and drains (sometimes referred to as a contact-level dielectric material layer), a first interconnect-level dielectric material layer 138, and a second interconnect-level dielectric material layer 140. The metal interconnect structures may include device contact via structures 142 formed in the first dielectric material layer 136 and contact a respective component of the CMOS circuitry 134, first metal line structures 144 formed in the first interconnect-level dielectric material layer 138, first metal via structures 146 formed in a lower portion of the second interconnect-level dielectric material layer 140, and second metal line structures 148 formed in an upper portion of the second interconnect-level dielectric material layer 140.

Each of the dielectric material layers (136, 138, 140) may include a dielectric material such as undoped silicate glass, a doped silicate glass, organosilicate glass, amorphous fluorinated carbon, porous variants thereof, or combinations thereof. Each of the metal interconnect structures (142, 144, 146, 148) may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, TiN, alloys thereof, and/or combinations thereof.

Other suitable metallic liner and metallic fill materials within the contemplated scope of disclosure may also be used. In one embodiment, the first metal via structures 146 and the second metal line structures 148 may be formed as integrated line and via structures by a dual damascene process. The dielectric material layers (136, 138, 140) are herein referred to as lower-lower-level dielectric material layers. The metal interconnect structures (142, 144, 146, 148) formed within in the lower-level dielectric material layers are herein referred to as lower-level metal interconnect structures.

While the disclosure is described using an embodiment in which an array of memory cells may be formed over the second line-and-via-level dielectric material layer 140, embodiments are expressly contemplated herein in which the array of memory cells may be formed at a different metal interconnect level.

An array of thin-film transistors and an array of ferroelectric memory cells (or other types of memory cells) may be subsequently deposited over the dielectric material layers (136, 138, 140) that have formed therein the metal interconnect structures (142, 144, 146, 148). The set of all dielectric material layer that are formed prior to formation of an array of thin-film transistors or an array of ferroelectric memory cells is collectively referred to as lower-level dielectric material layers (136, 138, 140). The set of all metal interconnect structures that is formed within the lower-level dielectric material layers (136, 138, 140) is herein referred to as first metal interconnect structures (142, 144, 146, 148). Generally, first metal interconnect structures (142, 144, 146, 148) formed within at least one lower-level dielectric material layer (136, 138, 140) may be formed over the semiconductor material layer 104 that is located in the substrate 102.

According to an embodiment, thin-film transistors may be subsequently formed in a metal interconnect level that overlies that metal interconnect levels that contain the lower-level dielectric material layers (136, 138, 140) and the first metal interconnect structures (142, 144, 146, 148). In one embodiment, a planar dielectric material layer having a uniform thickness may be formed over the lower-level dielectric material layers (136, 138, 140). The planar dielectric material layer is herein referred to as an insulating matrix layer 150. The insulating matrix layer 150 may include a dielectric material such as undoped silicate glass, a doped silicate glass, organosilicate glass, or a porous dielectric material, and may be deposited by chemical vapor deposition. The thickness of the insulating matrix layer 150 may be in a range from 20 nm (i.e., 200 angstrom) to 300 nm (i.e., 3000 angstrom), although lesser and greater thicknesses may also be used.

Generally, interconnect-level dielectric layers (such as the lower-level dielectric material layer (136, 138, 140)) containing therein the metal interconnect structures (such as the first metal interconnect structures (142, 144, 146, 148)) may be formed over semiconductor devices. The insulating matrix layer 150 may be formed over the interconnect-level dielectric layers. Other passive devices may be formed in BEOL processes. For example various capacitors, inductors, resistors, and integrated passive devices may be utilized with other BEOL devices.

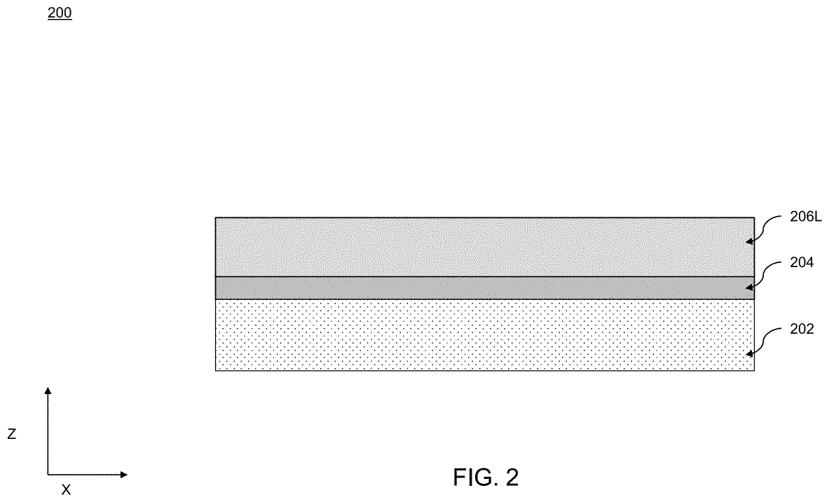

FIG. 2 is a vertical cross-sectional view of an intermediate structure 200 that may be used in the formation of a transistor structure, according to various embodiments. The intermediate structure 200 may include a substrate 202 which may be formed in a BEOL process. As such, the substrate 202 may be a dielectric layer (e.g., an inter-layer dielectric or insulating matrix layer 150 from FIG. 1).

The substrate 202 may include, for example, undoped silicate glass, a doped silicate glass (e.g., deposited by decomposition of tetraethylorthosilicate (TEOS)), organosilicate glass, silicon oxynitride, or silicon carbide nitride. Other dielectric materials are within the contemplated scope of disclosure. The dielectric material of the substrate 202 may be deposited by a conformal deposition process (such as a chemical vapor deposition process) or a self-planarizing deposition process (such as spin coating). The thickness of the substrate 202 may each be in a range from approximately 15 nm to approximately 60 nm, such as from approximately 20 nm to approximately 40 nm, although smaller and larger thicknesses may also be used.

The intermediate structure 200 of FIG. 2 may further include an etch-stop layer 204 and a first inter-layer dielectric layer 206L. The etch-stop layer 204 may include an etch-stop material such as silicon nitride, silicon carbide, silicon nitride carbide, or a dielectric metal oxide (such as aluminum oxide, titanium oxide, tantalum oxide, etc.). The etch-stop layer 204 may be deposited by a conformal or non-conformal deposition process. In one embodiment, the etch-stop layer 204 may be deposited by chemical vapor deposition (CVD), atomic layer deposition (ALD), or physical vapor deposition (PVD). A thickness of the etch-stop layer 204 may be in a range from approximately 2 nm to approximately 20 nm, such as from approximately 3 nm to approximately 12 nm, although smaller and larger thicknesses may also be used.

The first inter-layer dielectric layer 206L may include, but is not limited to, silicon dioxide, silicon nitride, silicon oxynitride, hafnium oxide, hafnium silicon oxide, hafnium tantalum oxide, hafnium titanium oxide, hafnium zirconium oxide, zirconium oxide, titanium oxide, aluminum oxide, hafnium dioxide-alumina, or various other insulating structures such as a multi-layer stack structure including alternating insulating layers. The first inter-layer dielectric layer 206L may be deposited by any suitable technique as CVD, ALD, PVD, plasma enhanced chemical vapor deposition (PECVD), etc.

In this example, the first inter-layer dielectric layer 206L may be formed as a planar blanket (i.e., un-patterned) layer having a planar top surface and a planar bottom surface. Excess portions of the first inter-layer dielectric layer 206L may be removed from above the top surface of the intermediate structure 200 by a planarization process, for example, by chemical mechanical planarization (CMP). A thickness of the first inter-layer dielectric layer 206L may be in a range from approximately 5 nm to approximately 50 nm, such as from approximately 20 nm to approximately 40 nm, although other embodiments may include smaller and larger thicknesses.

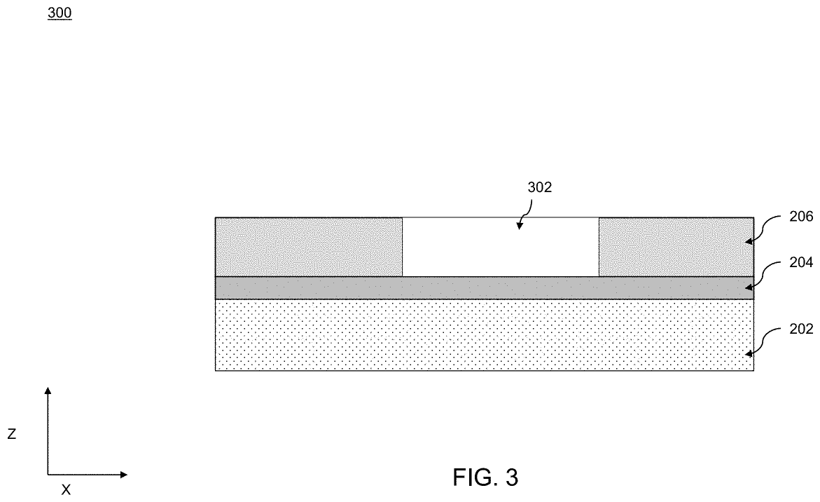

FIG. 3 is a vertical cross-sectional view of a further intermediate structure 300 that may be used in the formation of a transistor structure, according to various embodiments. The intermediate structure 300 may be formed by performing an anisotropic etch on the intermediate structure 200 of FIG. 2 to remove portions of the first inter-layer dielectric layer 206L to thereby form a first patterned inter-layer dielectric layer 206. In this regard, a photoresist (not shown) may be deposited over the intermediate structure 200 of FIG. 2. The photoresist may then be patterned using photolithography techniques to generate openings in the photoresist.

The patterned photoresist may then be used as a mask for patterning the first inter-layer dielectric layer 206L. In this regard, an anisotropic etch process may be performed to remove a region the first inter-layer dielectric layer 206L to thereby generate a via cavity 302. As shown in FIG. 3, the via cavity 302 may be formed by allowing the etch to proceed until a top surface of the etch-stop layer 204 is exposed. After etching, any residual photoresist may be removed by ashing or by dissolution with a solvent.

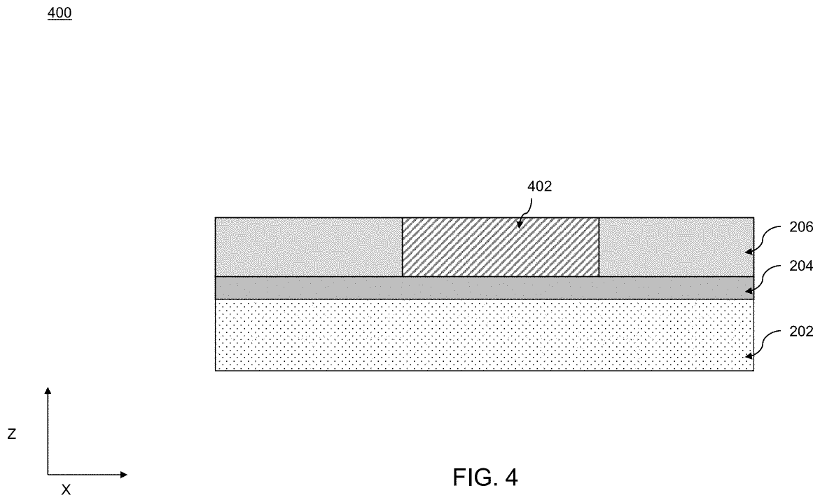

FIG. 4 is a vertical cross-sectional view of a further intermediate structure 400 that may be used in the formation of a transistor structure, according to various embodiments. In this regard, the intermediate structure 400 includes a gate electrode 402 formed in the first patterned inter-layer dielectric layer 206. The gate electrode 402 may formed by depositing a conductive material in the via cavity 302 of FIG. 3. The conductive material may include a metallic liner material and a metallic fill material. The metallic liner material may include a conductive metallic nitride or a conductive metallic carbide such as TiN, TiN/W, Ti/Al/Ti, TaN, WN, TiC, TaC, and/or WC. The metallic fill material may include W, Cu, Al, Co, Ru, Mo, Ta, Ti, TiN, alloys thereof, and/or combinations thereof. Other suitable metallic liner and metallic fill materials within the contemplated scope of this disclosure may also be used. A thickness of the gate electrode 402 may be in a range from approximately 5 nm to approximately 50 nm, such as from approximately 20 nm to approximately 40 nm, although other embodiments may include smaller and larger thicknesses.

The metallic liner material and metallic fill materials may be formed by suitable deposition process, which may include one or more of a CVD process, a PVD process, an ALD process, an electroplating process, etc. Other suitable deposition processes are within the contemplated scope of disclosure. Excess portions of the conductive material may be removed from above a horizontal plane including the top surface of the first patterned inter-layer dielectric layer 206 by a planarization process. The planarization process may include use of a CMP process although other suitable planarization processes may be used.

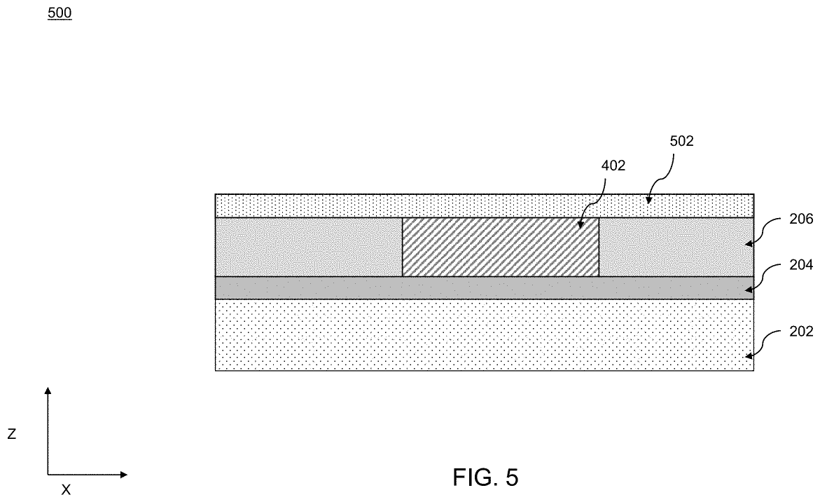

FIG. 5 is a vertical cross-sectional view of a further intermediate structure 500 that may be used in the formation of a transistor structure, according to various embodiments. The intermediate structure 500 may be formed by depositing a gate dielectric layer 502 over the intermediate structure 400 of FIG. 4. The gate dielectric layer 502 may include, but is not limited to, silicon dioxide, silicon nitride, silicon oxynitride, hafnium oxide, hafnium silicon oxide, hafnium tantalum oxide, hafnium titanium oxide, hafnium zirconium oxide, zirconium oxide, titanium oxide, aluminum oxide, hafnium dioxide-alumina, or various other insulating structures such as a multi-layer stack structure including alternating insulating layers. Other suitable dielectric materials are within the contemplated scope of disclosure. In other embodiments, the gate dielectric layer 502 may include an alternating multi-layer structure including silicon oxide and silicon nitride. In other embodiments, the gate dielectric layer 502 may include a ferroelectric material, as described in greater detail below.

The gate dielectric layer 502 may be formed by any suitable technique as ALD, CVD, PECVD, PVD, etc. Excess portions of the gate dielectric layer 502 may be removed from above a horizontal plane of the intermediate structure 500 including a top surface of the gate dielectric layer 502 by a planarization process. The planarization process may include use of a CMP process although other suitable planarization processes may be used. A thickness of the gate dielectric layer 502 may be in a range from approximately 3 nm to approximately 15 nm, such as from approximately 5 nm to approximately 12 nm, although other embodiments may include smaller and larger thicknesses. Following the deposition of the gate dielectric layer 502, the intermediate structure 500 may optionally be annealed. The optional annealing process may be performed at a temperature in a range from 200° C. to 400° C. using a rapid thermal annealing or furnace annealing process. The annealing may be performed in an environment of nitrogen, oxygen, or a mixture thereof.

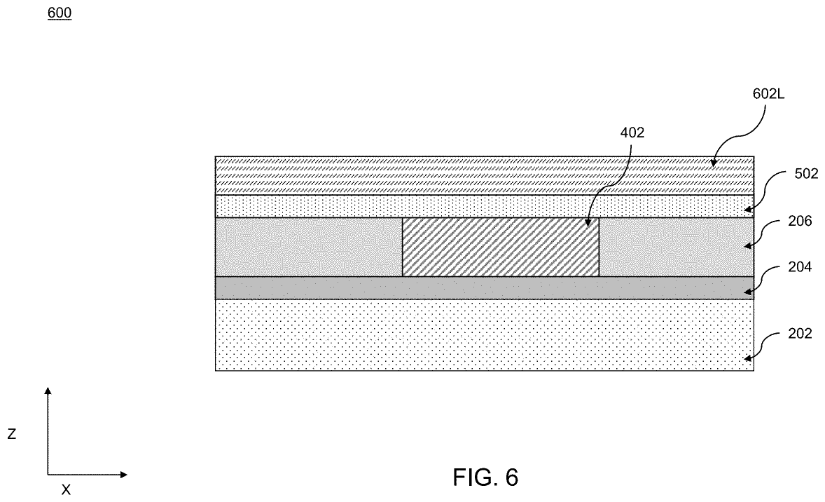

FIG. 6 is a vertical cross-sectional view of a further intermediate structure 600 that may be used in the formation of a transistor structure, according to various embodiments. The intermediate structure 600 may be formed by depositing an oxide semiconductor layer 602L over the intermediate structure 500 of FIG. 5. The oxide semiconductor layer 602L may be a semiconducting material including, but not limited to, amorphous silicon, InGaZnO, InGaO, InWO, InZnO, InSnO, ZnO, GaO, InO, and alloys thereof. Other suitable semiconducting materials are within the contemplated scope of disclosure. For example, in various embodiments, the oxide semiconductor layer 602L may include a composition given by InₓGa_{y}Zn_{z}MO, wherein 0<x<1; 0≤y≤1; 0≤z≤1; and M is one of Ti, Al, Ag, Ce, and Sn. The oxide semiconductor layer 602L may be formed by any suitable method such as ALD, CVD, PECVD, PVD, etc.

In this example, the oxide semiconductor layer 602L may be formed as a planar blanket (i.e., un-patterned) layer having a planar top surface and a planar bottom surface. Excess portions of the oxide semiconductor layer 602L may be removed from above the top surface of the intermediate structure 600 by a planarization process, for example, by CMP. A thickness of the first inter-layer dielectric layer 206L may be in a range from approximately 3 nm to approximately 20 nm, such as from approximately 5 nm to approximately 15 nm, although other embodiments may include smaller and larger thicknesses. Following the deposition of the oxide semiconductor layer 602L, the intermediate structure 600 may optionally be annealed. The optional annealing process may be performed at a temperature in a range from 200° C. to 400° C. using a rapid thermal annealing or furnace annealing process. The annealing may be performed in an environment of nitrogen, oxygen, or a mixture thereof.

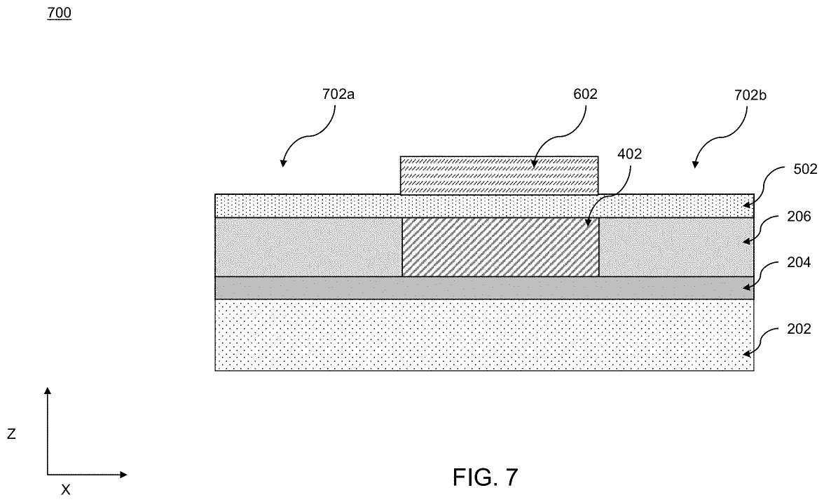

FIG. 7 is a vertical cross-sectional view of a further intermediate structure 700 that may be used in the formation of a transistor structure, according to various embodiments. The intermediate structure 700 may be formed by performing an anisotropic etch on the intermediate structure 600 of FIG. 6 to remove portions of the oxide semiconductor layer 602L to thereby form an active layer 602 for a transistor structure to be formed subsequently. In this regard, a photoresist (not shown) may be deposited over the intermediate structure 600 of FIG. 6. The photoresist may then be patterned using photolithography techniques to generate openings in the photoresist.

The patterned photoresist may then be used as a mask for patterning the oxide semiconductor layer 602L. In this regard, an anisotropic etch process may be performed to remove a region the oxide semiconductor layer 602L having a first portion 702a and a second portion 702b. As shown, in FIG. 7, the first portion 702a and the second portion 702b may be formed by etching the oxide semiconductor layer 602L to thereby expose respective regions of the gate dielectric layer 502. After etching, any residual photoresist may be removed by ashing or by dissolution with a solvent.

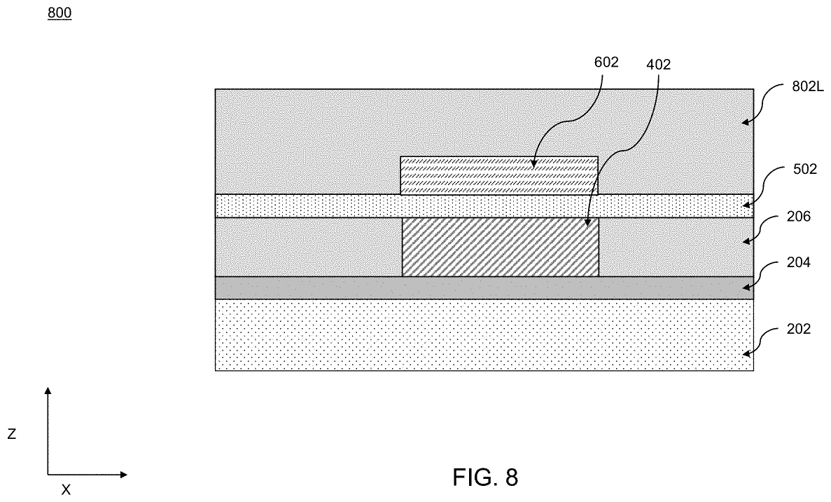

FIG. 8 is a vertical cross-sectional view of a further intermediate structure 800 that may be used in the formation of a transistor structure, according to various embodiments. The intermediate structure 800 may be formed by depositing a second inter-layer dielectric layer 802L over the intermediate structure 700 of FIG. 7. The second inter-layer dielectric layer 802L may include the same material as the first inter-layer dielectric layer 206L or may include a different material. In this regard, the second inter-layer dielectric layer 802L may include, but is not limited to, silicon dioxide, silicon nitride, silicon oxynitride, hafnium oxide, hafnium silicon oxide, hafnium tantalum oxide, hafnium titanium oxide, hafnium zirconium oxide, zirconium oxide, titanium oxide, aluminum oxide, hafnium dioxide-alumina, or various other insulating structures such as a multi-layer stack structure including alternating insulating layers. The second inter-layer dielectric layer 802L may be deposited by any suitable technique as CVD, ALD, PVD, PECVD), etc.

In this example, the second inter-layer dielectric layer 802L may be formed as a planar blanket (i.e., un-patterned) layer having a planar top surface and a planar bottom surface. Excess portions of the second inter-layer dielectric layer 802L may be removed from above the top surface of the intermediate structure 800 by a planarization process, for example, by CMP. A thickness of the second inter-layer dielectric layer 802L may be in a range from approximately 5 nm to approximately 50 nm, such as from approximately 20 nm to approximately 40 nm, although other embodiments may include smaller and larger thicknesses.

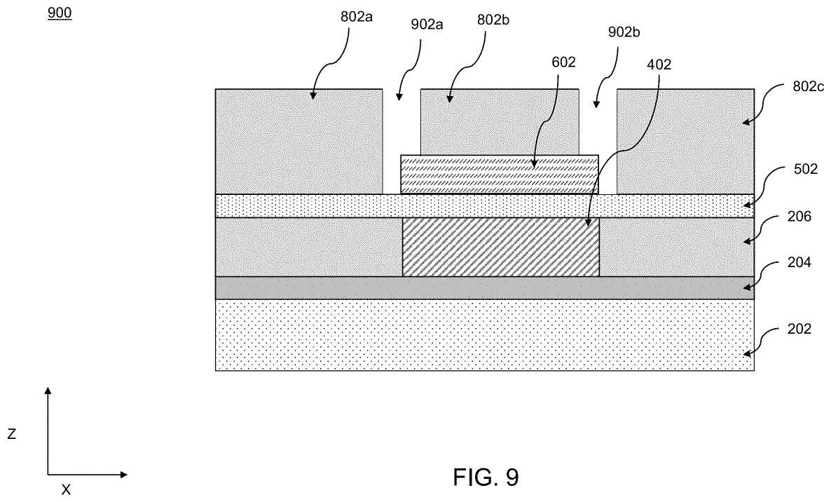

FIG. 9 is a vertical cross-sectional view of a further intermediate structure 900 that may be used in the formation of a transistor structure, according to various embodiments. The intermediate structure 900 may be formed by performing an anisotropic etch on the intermediate structure 800 of FIG. 8 to remove portions of the second inter-layer dielectric layer 802L to thereby form a second patterned inter-layer dielectric layer having a first portion 802a, a second portion 802b, and a third portion 802c. In this regard, a photoresist (not shown) may be deposited over the intermediate structure 800 of FIG. 8. The photoresist may then be patterned using photolithography techniques to generate openings in the photoresist.

The patterned photoresist may then be used as a mask for patterning the second inter-layer dielectric layer 802L. An anisotropic etch process may be performed to remove respective first and second regions of the second inter-layer dielectric layer 802L to thereby generate a first via cavity 902a and a second via cavity 902b. As shown in FIG. 9, the first via cavity 902a and the second via cavity 902b may be formed by allowing the etch to proceed until portions of the gate dielectric layer 502 and active layer 602 exposed. After etching, any residual photoresist may be removed by ashing or by dissolution with a solvent.

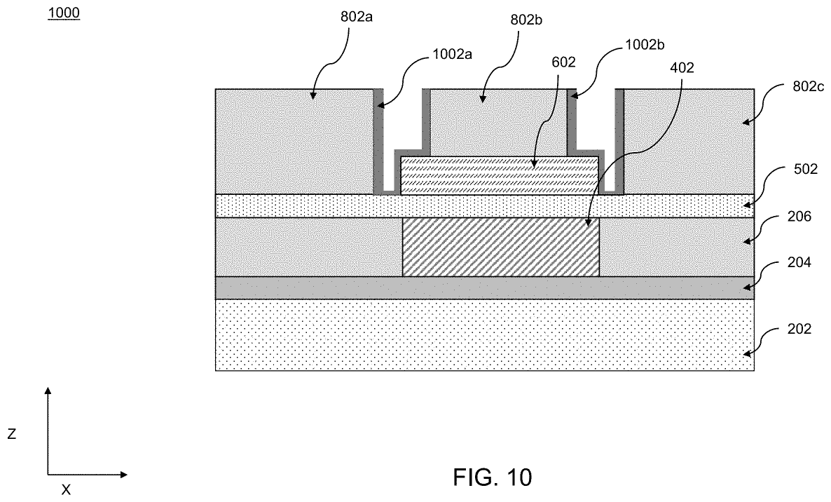

FIG. 10 is a vertical cross-sectional view of a further intermediate structure 1000 that may be used in the formation of a transistor structure, according to various embodiments. The intermediate structure 1000 of FIG. 10 may be formed by conformally depositing a first hydrogen-rich material layer 1002a in the first via cavity 902a (e.g., see FIG. 9) and conformally depositing a second hydrogen-rich material layer 1002b in the second via cavity 902b by using a deposition technique that includes hydrogen precursors/reactants. The first hydrogen-rich material layer 1002a and the second hydrogen-rich material layer 1002b may be formed by depositing a conformal layer (not shown) over the intermediate structure 900 of FIG. 9 followed by performing a planarization process. In this regard, after deposition of the hydrogen-rich layer over the intermediate structure 900 of FIG. 9, a CMP or other planarization process may be performed to remove excess portions of the hydrogen-rich layer over a top surface of the inter-layer dielectric layer (802a, 802b, 802c) of FIGS. 9 and 10.

The first hydrogen-rich material layer 1002a and the second hydrogen-rich material layer 1002b may include, but are not limited to, TiN, WN, WCN Co, PdCo, Mo, etc., and alloys of W, Mo, Co, Pd, Ti, and mixtures thereof, with or without N and/or O, and may be deposited using CVD, ALD, or by other processes that include hydrogen precursors/reactants. A thickness of the first hydrogen-rich material layer 1002a and the second hydrogen-rich material layer 1002b may be in a range from approximately 1 nm to approximately 50 nm, such as from approximately 20 nm to approximately 40 nm, although other embodiments may include smaller and larger thicknesses.

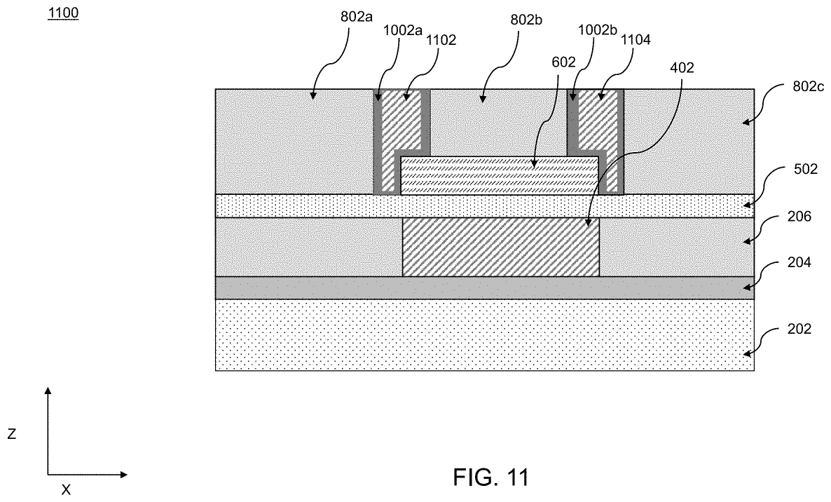

FIG. 11 is a vertical cross-sectional view of an embodiment transistor structure 1100, after formation of a source electrode 1102 and a drain electrode 1104 respectively in the first via cavity 902a and the second via cavity 902b (e.g., see FIG. 9) of the intermediate structure 1000 of FIG. 10, according to various embodiments. As shown in FIG. 11, the source electrode 1102 and the drain electrode 1104 may be respectively formed over the first hydrogen-rich material layer 1002a and the second hydrogen-rich material layer 1002b.

The source electrode 1102 and drain electrode 1104 may formed by depositing a conductive material into the first via cavity 902a and the second via cavity 902b, respectively. The conductive material deposited may include a metallic liner material and a metallic fill material. The metallic liner material may include a conductive metallic nitride or a conductive metallic carbide such as TiN, TiN/W, Ti/Al/Ti, TaN, WN, TiC, TaC, and/or WC. A thickness of the metallic liner material may be in a range from approximately 1 nm to approximately 10 nm, such as from approximately 3 nm to approximately 8 nm, although smaller and larger thicknesses may also be used.

The metallic fill material may include W, Cu, Al, Co, Ru, Mo, Ta, Ti, TiN, alloys thereof, and/or combinations thereof. Other suitable metallic liner and metallic fill materials within the contemplated scope of this disclosure may also be used. A thickness of the metallic fill material may be in a range from approximately 10 nm to approximately 50 nm, such as from approximately 20 nm to approximately 40 nm, although smaller and larger thicknesses may also be used.

The metallic liner material and metallic fill materials may be formed by suitable deposition process, which may include one or more of a CVD process, a PVD process, an ALD process, an electroplating process, etc. Other suitable deposition processes are within the contemplated scope of disclosure. Excess portions of the conductive material may be removed from above a horizontal plane including the top surface of the interlayer dielectric layer (802a, 802b, 802c) by a planarization process such as CMP, although other suitable planarization processes may be used.

As shown in FIG. 11, the transistor structure 1100 includes a gate electrode 402, an active layer 602, a gate dielectric layer 502 separating the active layer 602 from the gate electrode 402, a source electrode 1102, a drain electrode 1104; and a hydrogen-rich material layer (1102a, 1102b) separating the source electrode 1102 and the drain electrode 1104 from the active layer 602. In this regard, the first hydrogen-rich material layer 1002a may separate the source electrode 1102 from the active layer 602 and the second hydrogen-rich material layer 1002b may separate the drain electrode 1104 from the active layer 602.

The presence of hydrogen in the first hydrogen-rich material layer 1002a and the second hydrogen-rich material layer 1002b may act to reduce Schottky barriers between the source electrode 1102 and the active layer 602, and between the drain electrode 1104 and the active layer 602, respectively. In this regard, the hydrogen in the first hydrogen-rich material layer 1002a and the second hydrogen-rich material layer 1002b may act as a doner dopant that may increase a carrier concentration in the source electrode 1102, the drain electrode 1104, and the active layer 602. Reduction of the Schottky barriers may lead to an increase in on-current and a decrease of contact resistance relative to comparable devices that do not include the first hydrogen-rich material layer 1002a and the second hydrogen-rich material layer 1002b.

As mentioned above, the active layer 602 may include a semiconducting material including, but not limited to, amorphous silicon, InGaZnO, InGaO, InWO, InZnO, InSnO, ZnO, GaO, InO, and alloys thereof. Other suitable semiconducting materials are within the contemplated scope of disclosure. For example, in various embodiments, the oxide semiconductor layer 602L may include a composition given by InₓGa_{y}Zn_{z}MO, wherein 0<x<1; 0≤y≤1; 0≤z≤1; and M is one of Ti, Al, Ag, Ce, and Sn.

The gate dielectric layer 502 may include a high-k dielectric material including one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina. In other embodiments, the gate dielectric layer 502 may include an alternating multi-layer structure including silicon oxide and silicon nitride. Other suitable dielectric materials are within the contemplated scope of disclosure.

In still further embodiments, the gate dielectric layer 502 may include a ferroelectric (FE) material. As such, with the inclusion of a ferroelectric material for the gate dielectric layer 502, the transistor structure 1100 may be configured as a ferroelectric field-effect transistor (FeFET) structure. FeFETs are emerging devices, in which a FE layer is utilized as a gate dielectric layer 502 between a gate electrode 402 and an active layer 602 (also known as a “channel region”). A permanent electrical field polarization in the FE layer causes this type of device to retain the transistor's state (on or off) in the absence of any electrical bias.

A ferroelectric material is a material that may have spontaneous nonzero electrical polarization (i.e., non-zero total electrical dipole moment) when the external electrical field is zero. The spontaneous electrical polarization may be reversed by a strong external electric field applied in the opposite direction. The electrical polarization is dependent not only on the external electrical field at the time of measurement, but also on the history of the external electrical field, and thus, has a hysteresis loop. The maximum of the electrical polarization is referred to as saturation polarization. The electrical polarization that remains after an external electrical field that induces saturation polarization is no longer applied (i.e., turned off) is referred to as remnant polarization. The magnitude of the electrical field that needs to be applied in the opposite direction of the remnant polarization in order to achieve zero polarization is referred to as coercive electrical field.

In some embodiments, a ferroelectric structure, such as a FeFET structure, may form a memory cell of a memory array. In a FeFET-based memory cell, the FE material located between the gate electrode and the channel region of the semiconductor material layer may have two stable remnant polarization states. In one remnant polarization state, the FeFET may be permanently in an “on” state, and in the other remnant polarization state, the FeFET may be permanently in an “off” state. Thus, the polarization state of the FE layer may be used to encode information (i.e., bits) in a non-volatile manner.

The logic state of the FeFET-based memory cell may be read non-destructively by sensing the resistance across the terminals (e.g., source and drain terminals) of the FeFET. The difference between the threshold voltage of the FeFET in the “on” state and in the “off” state may be referred to as the “memory window” (MW) of the FeFET-based memory cell. To re-program the FeFET-based memory cell, a sufficiently high voltage may be applied to the FeFET to induce the polarization state of the FE material to reverse and thereby change the logic state of the FeFET memory cell.

In various embodiments, the gate dielectric layer 502 may include a ferroelectric material, which may include, but may not be limited to a hafnium oxide-based ferroelectric material, such as HfₓZr₁₋ₓO_{y} where 0≤x≤1 (e.g., Hf_{0.5}Zr_{0.5}O₂), HfO₂, HfSiO, HfLaO, etc. In various embodiments, the gate dielectric layer 502 may include hafnium zirconium oxide (HZO) doped with atoms having a smaller ionic radius than hafnium (e.g., Al, Si, etc.) and/or doped with atoms having a larger ionic radius than hafnium (e.g., La, Sc, Ca, Ba, Gd, Y, Sr, etc.).

The dopant(s) may be at a concentration configured to improve a ferroelectric property of the gate dielectric layer 502, such as increasing the remnant polarization. In various embodiments, dopants having a smaller ionic radius than hafnium and/or dopants having a larger ionic radius than hafnium may have a doping concentration that is between about 1 mol. % and about 20 mol. %. In some embodiments, the FE material may include oxygen vacancies. Oxygen vacancies in the FE material may promote the formation of orthorhombic (o-phase) crystal phases in the FE material. Other suitable materials for the gate dielectric layer 502 are within the contemplated scope of disclosure, including, without limitation, ZrO₂, PbZrO₃, Pb[ZrₓTi₁₋ₓ]O₃, (0≤x≤1) (PZT), Pb₁₋ₓLaₓZr_{1-y}Ti_{y}O₃ (PLZT), BaTiO₃, PbTiO₃, PbNb₂O₆, LiNbO₃, LiTaO₃, PbMg_{⅓}Nb_{⅔}O₃ (PMN), PbSc_{½}Ta_{½}O₃ (PST), SrBi₂Ta₂O₉ (SBT), Bi_{½}Na_{½}TiO₃, and combinations thereof.

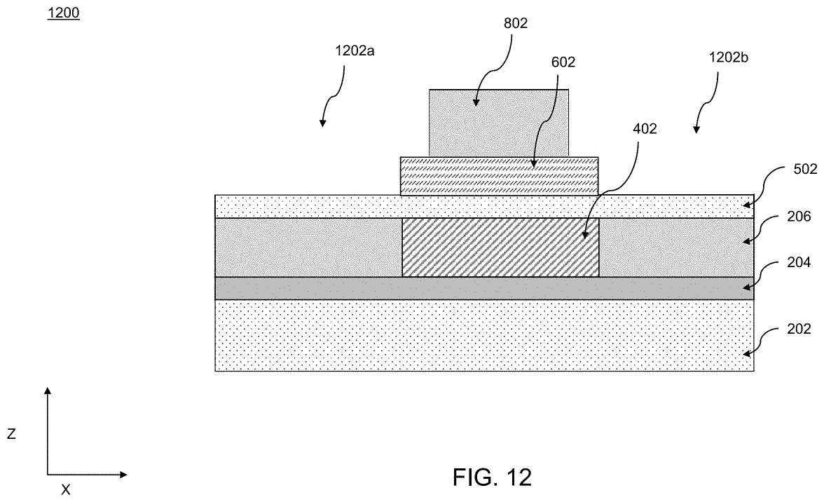

FIG. 12 is a vertical cross-sectional view of a further intermediate structure 1200 that may be used in the formation of a further transistor structure, according to various embodiments. The intermediate structure 1200 may be formed by performing an anisotropic etch on the intermediate structure 800 of FIG. 8 to remove portions of the second inter-layer dielectric layer 802L to thereby form a second patterned inter-layer dielectric layer 802. In this regard, a photoresist (not shown) may be deposited over the intermediate structure 800 of FIG. 8. The photoresist may then be patterned using photolithography techniques to generate openings in the photoresist.

The patterned photoresist may then be used as a mask for patterning the second inter-layer dielectric layer 802L. An anisotropic etch process may be performed to remove respective first and second regions of the second inter-layer dielectric layer 802L to thereby generate a first etched region 1202a and a second etched region 1202b. As shown in FIG. 12, the first etched region 1202a and the second etched region 1202b may be formed by allowing the etch to proceed until portions of the gate dielectric layer 502 and active layer 602 are exposed. After etching, any residual photoresist may be removed by ashing or by dissolution with a solvent.

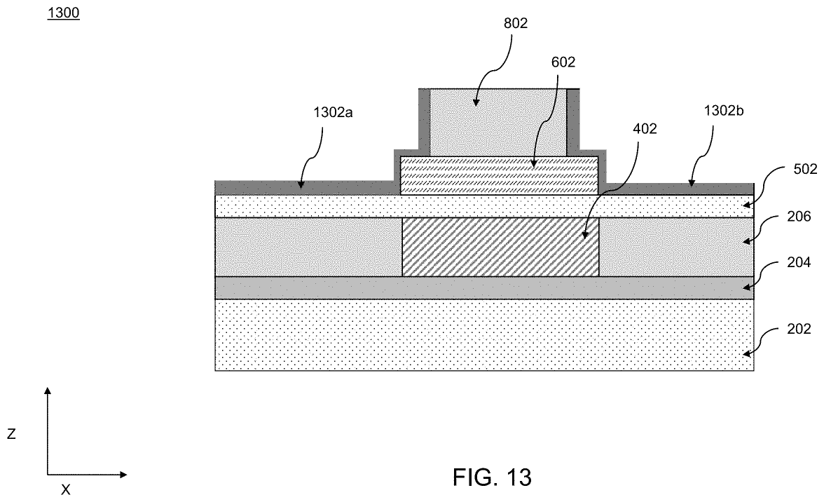

FIG. 13 is a vertical cross-sectional view of a further intermediate structure 1300 that may be used in the formation of a transistor structure, according to various embodiments. The intermediate structure 1300 of FIG. 13 may be formed by forming a first hydrogen-rich material layer 1302a over the first etched region 1202a and forming a second hydrogen-rich material layer 1302b over the second etched region 1202b of the intermediate structure 1200 of FIG. 12. The first hydrogen-rich material layer 1302a and the second hydrogen-rich material layer 1302b may be formed by depositing a blanket layer of hydrogen-rich material (not shown) over the intermediate structure 1200 of FIG. 12 followed by performing a planarization process. In this regard, after deposition of the hydrogen-rich layer over the intermediate structure 1200 of FIG. 12, a CMP or other planarization process may be performed to remove excess portions of the hydrogen-rich layer over a top surface of the second patterned inter-layer dielectric layer 802.

The first hydrogen-rich material layer 1302a and the second hydrogen-rich material layer 1302b may include, but are not limited to, TiN, WN, WCN Co, PdCo, Mo, etc., and alloys of W, Mo, Co, Pd, Ti, and mixtures thereof, with or without N and/or 0, and may be deposited using CVD, ALD, or by other processes that include hydrogen precursors/reactants. A thickness of the first hydrogen-rich material layer 1302a and the second hydrogen-rich material layer 1302b may be in a range from approximately 1 nm to approximately 50 nm, such as from approximately 20 nm to approximately 40 nm, although other embodiments may include smaller and larger thicknesses.

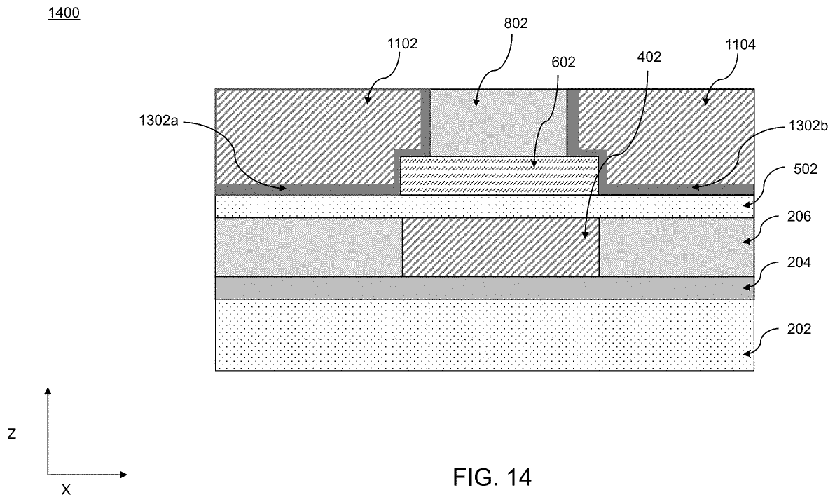

FIG. 14 is a vertical cross-sectional view of a further embodiment transistor structure 1400, after formation of a source electrode 1102 and a drain electrode 1104 respectively over first hydrogen-rich material layer 1302a and the second hydrogen-rich material layer 1302b of the intermediate structure 1300 of FIG. 13, according to various embodiments.

The source electrode 1102 and drain electrode 1104 may include a metallic liner material and a metallic fill material. The metallic liner material may include a conductive metallic nitride or a conductive metallic carbide such as TiN, TiN/W, Ti/Al/Ti, TaN, WN, TiC, TaC, and/or WC. A thickness of the metallic liner material may be in a range from approximately 1 nm to approximately 10 nm, such as from approximately 3 nm to approximately 8 nm, although smaller and larger thicknesses may also be used.

The metallic fill material may include W, Cu, Al, Co, Ru, Mo, Ta, Ti, TiN, alloys thereof, and/or combinations thereof. Other suitable metallic liner and metallic fill materials within the contemplated scope of this disclosure may also be used. A thickness of the metallic fill material may be in a range from approximately 10 nm to approximately 50 nm, such as from approximately 20 nm to approximately 40 nm, although smaller and larger thicknesses may also be used.

The metallic liner material and metallic fill materials may be formed by suitable deposition process, which may include one or more of a CVD process, a PVD process, an ALD process, an electroplating process, etc. Other suitable deposition processes are within the contemplated scope of disclosure. Excess portions of the conductive material may be removed from above a horizontal plane including the top surface of the second patterned inter-layer dielectric layer 802 by a planarization process such as CMP, although other suitable planarization processes may be used.

As shown in FIG. 14, the transistor structure 1400 includes a gate electrode 402, an active layer 602, a gate dielectric layer 502 separating the active layer 602 from the gate electrode 402, a source electrode 1102, a drain electrode 1104, and a hydrogen-rich material layer (1302a, 1302b) separating the source electrode 1102 and the drain electrode 1104 from the active layer 602. In this regard, the first hydrogen-rich material layer 1302a separates the source electrode 1102 from the active layer 602 and the second hydrogen-rich material layer 1302b separates the drain electrode 1104 from the active layer 602.

As with the embodiment transistor structure 1100 of FIG. 11, the presence of the first hydrogen-rich material layer 1302a and the second hydrogen-rich material layer 1302b in the embodiment transistor structure 1400 of FIG. 14 may improve device performance by reducing Schottky barriers respectively between the source electrode 1102 and the active layer 602, and between the drain electrode 1104 and the active layer 602. The presence of the first hydrogen-rich material layer 1302a and the second hydrogen-rich material layer 1302b may also act to reduce the contact resistance of the transistor structure 1400 and may thereby increase the on-current relative to similar embodiments that do not include the first hydrogen-rich material layer 1302a and the second hydrogen-rich material layer 1302b.

The above-described embodiment transistor structures (1100, 1400) are described as including a substrate 202, an etch stop layer 204, a first patterned inter-layer dielectric layer 206, a gate electrode 402, a gate dielectric layer 502, an active layer 602, a hydrogen-rich material layer (1102a, 1102b, 1302a, 1302b), a source electrode 1102, a drain electrode 1104, and a second patterned inter-layer dielectric layer 802. Further, the source electrode 1102 and the drain electrode 1104 are described as including a metallic liner and metallic fill materials. Various other embodiments may include additional layers or fewer layers. For example, in some embodiments, the metallic fill material may be deposited directly on the hydrogen-rich material layer (1102a, 1102b, 1302a, 1302b) without depositing an additional metallic liner material.

In further embodiments, an additional metallic layer (i.e., a “glue layer”) may be deposited between the second patterned inter-layer dielectric layer 802 and the hydrogen-rich material layer (1102a, 1102b, 1302a, 1302b). The additional metallic layer may include materials similar to those used in the metallic liner material described above (e.g., TiN, TaN, WN, TiC, TaC, and WC) and may have a thickness in a range from approximately 1 nm to approximately 10 nm, such as such as from approximately 3 nm to approximately 8 nm, although smaller and larger thicknesses may also be used.

In further embodiments, the metallic fill material of the source electrode 1102 and the drain electrode 1104 may be replaced with a volume of the hydrogen-rich material. In still further embodiments, a capping layer may be formed between the active layer 602 and the second patterned inter-layer dielectric layer 802. The capping layer may include a material that is similar to materials used for the inter-layer dielectric layers (206, 802) and may have a thickness in a range from approximately 1 nm to 20 nm, such as from approximately 5 nm to 15 nm, although smaller and larger thicknesses may also be used. The above-described additional embodiments including greater or fewer layers may be mixed and matched in various ways to form multiple different embodiment transistor structures (1100, 1400). All such alternative embodiments are considered to be within the contemplated scope of this disclosure and no specific embodiment described above should be interpreted as limiting.

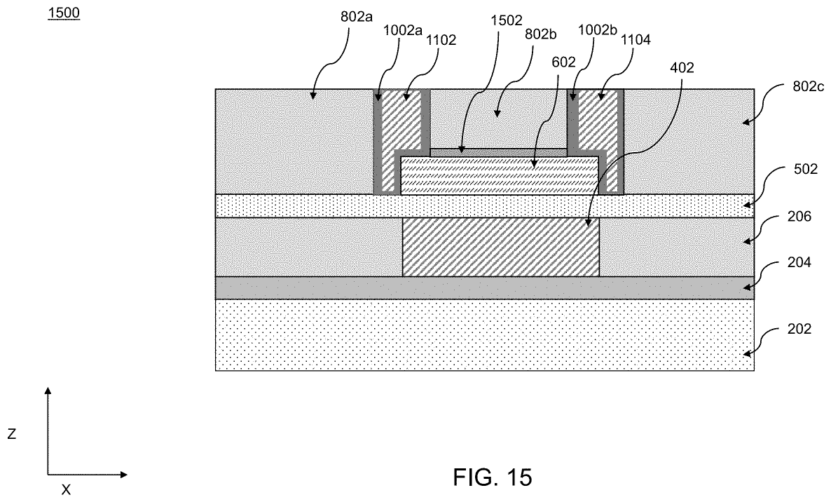

FIGS. 15, 16, 17 are vertical cross-sectional views of a further embodiment transistor structures 1500, 1600, and 1700, respectively, according to various embodiments. Each of the transistor structures 1500, 1600, and 1700 may include one or more additional layers relative to the transistor structures 1100 and 1400 of FIGS. 11 and 14, respectively. In this regard, the transistor structure 1500 of FIG. 15 includes a capping layer 1502 formed over the active layer 602 and separating the active layer 602 from the portion 802b of the second patterned inter-layer dielectric layer.

In certain embodiments, the capping layer 1502 may include the same or similar materials as those materials that form the inter-layer dielectric layer (802a, 802b, 802c). However, the capping layer may be deposited using a deposition technique or tool settings that are different from the technique/tool settings used to deposit the inter-layer dielectric layer (802a, 802b, 802c) For example, the capping layer 1502 may be deposited using low plasma power ALD or CVD or low bias PVD to thereby avoid damage to the active layer 602.

The thickness of the capping layer 1502 may be in a range from approximately 1 nm to approximately 20 nm, such as from approximately 5 nm to approximately 15 nm, although smaller and larger thicknesses may also be used.

The capping layer 1502 may include, but is not limited to, silicon dioxide, silicon nitride, silicon oxynitride, hafnium oxide, hafnium silicon oxide, hafnium tantalum oxide, hafnium titanium oxide, hafnium zirconium oxide, zirconium oxide, titanium oxide, aluminum oxide, hafnium dioxide-alumina, or various other insulating structures such as a multi-layer stack structure including alternating insulating layers.

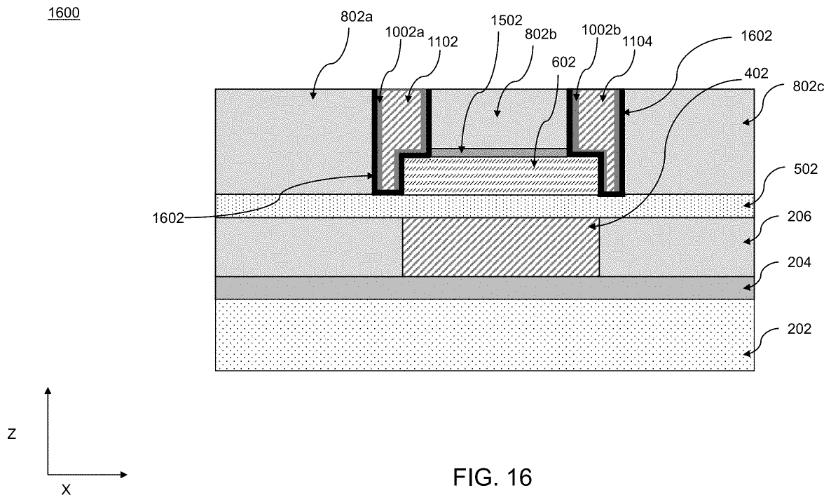

As shown in FIG. 16, the transistor structure 1600 may further include a glue layer 1602 that separates the first hydrogen-rich material layer 1002a and the second hydrogen-rich material layer 1002b from surrounding structures, such as second patterned inter-layer dielectric layer (802a, 802b, 802c), the capping layer 1502, and the active layer 602. The thickness of the glue layer 1602 may be in a range from approximately 1 nm to approximately 10 nm, such as from approximately 3 nm to approximately 8 nm, although smaller and larger thicknesses may also be used. The glue layer 1602 may include W, Cu, Al, Co, Ru, Mo, Ta, Ti, TiN, alloys thereof, and/or combinations thereof. The glue layer 1602 may assist in adhering the source electrode material and the drain electrode material to the semiconducting material 602.

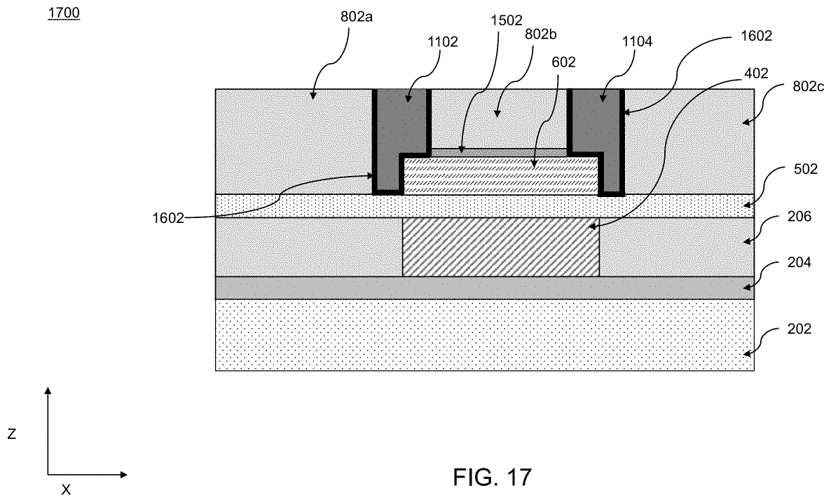

As shown in FIG. 17, the transistor structure 1700 may further include a source electrode 1102 and a drain electrode 1104 in which the metallic fill material of previous embodiments is replaced by a hydrogen-rich material. Thus, rather than forming a thin layer of hydrogen-rich material layer (1002a, 1002b, 1302a, 1302b), as in the embodiment transistor structures 1100, 1400, 1500, and 1600 (e.g., see FIGS. 11, and 14 to 16, respectively), the hydrogen-rich material in the transistor structure 1700 forms a uniform volume of material that forms the source electrode 1102 and the drain electrode. As with the embodiment transistor structure 1600 (e.g., see FIG. 16), the transistor structure 1700 of FIG. 17 further includes the capping layer 1502 and the glue layer 1602. The glue layer 1602 separates the source electrode 1102 and the drain electrode 1104 from surrounding structures, such as second patterned inter-layer dielectric layer (802a, 802b, 802c), the capping layer 1502, and the active layer 602.

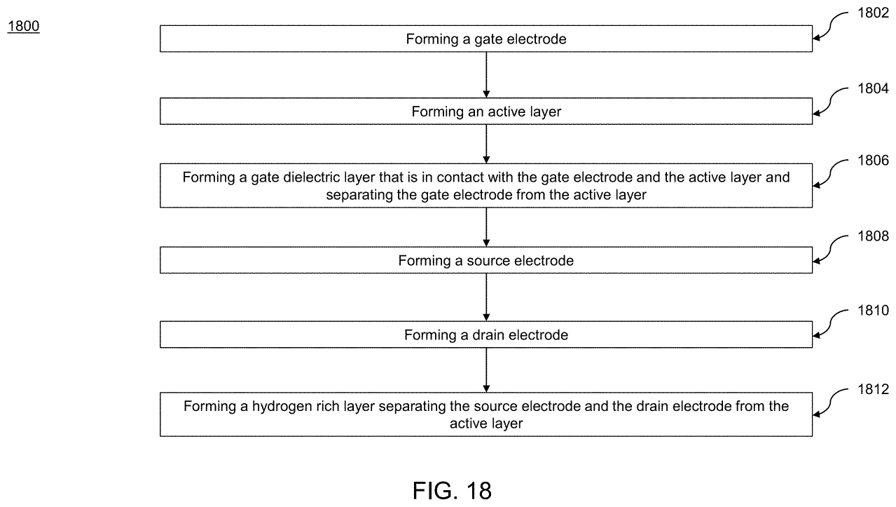

FIG. 18 is a flowchart illustrating operations of a method 1800 of manufacturing a transistor structure, according to various embodiments. In a first operation 1802, the method 1800 may include forming a gate electrode 402. As described above, the gate electrode 402 may be formed by forming an etch-stop layer 204 over a substrate 202 and forming an inter-layer dielectric layer 206L over the etch-stop layer 204 (e.g., see FIG. 2). The inter-layer dielectric layer 206L may then be etched to form the first patterned inter-layer dielectric layer 206 having a via cavity 302, as shown in FIG. 3. A conductive material may then be deposited in the via cavity 302 followed by planarization (e.g., using CMP) to thereby form the gate electrode 402.

In operation 1804, the method 1800 may further include forming an active layer 602, and in operation 1806, the method 1800 may include forming a gate dielectric layer 502 that is in contact with the gate electrode 402 and the active layer 602 and separating the gate electrode 402 from the active layer 602. As described above, the gate dielectric layer 502 may be formed by depositing a high-k dielectric material over the gate electrode 402. In this regard, the gate dielectric layer 502 may include, but is not limited to, one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina. In further embodiments, forming the gate dielectric layer 502 may include forming an alternating multi-layer structure including silicon oxide and silicon nitride over the gate electrode, or forming a ferroelectric material over the gate electrode 402.

The active layer 602 may be formed by depositing and patterning one of amorphous silicon, InGaZnO, InGaO, InWO, InZnO, InSnO, ZnO, GaO, InO, InZnO, and alloys thereof over the gate dielectric layer 502. Forming the active layer 602 may alternatively include depositing a material having a composition given by InₓGa_{y}Zn_{z} MO, wherein 0<x<1; 0≤y≤1; 0≤z≤1; and M is one of Ti, Al, Ag, Ce, and Sn.

In operation 1808, the method 1800 may include forming a source electrode 1102 and in operation 1810, the method 1800 may include forming a drain electrode 1104. In operation 1812, the method 1800 may further include forming a hydrogen-rich material layer (1002a, 1002b, 1302a, 1302b) separating the source electrode 1102 and the drain electrode 1104 from the active layer 602. In this regard, forming the source electrode 1102, forming the drain electrode 1104, and forming the hydrogen-rich material layer (1002a, 1002b, 1302a, 1302b) further includes forming an inter-layer dielectric layer 802L (e.g., see FIG. 8) over the active layer 602 and etching the second inter-layer dielectric layer 802L to thereby generate a first via cavity 902a and a second via cavity 902b, such that the first via cavity 902a (or the first etched region 1202a) and the second via cavity 902b (or the second etched region 1202b) each expose respective surfaces of the active layer 602 and the gate dielectric layer 502 (e.g., see FIGS. 9 and 12).

The method 1800 may further include performing a chemical vapor deposition process or an atomic layer deposition process to deposit TiN, WN, WCN Co, PdCo, Mo, etc., and alloys of W, Mo, Co, Pd, Ti, and mixtures thereof, with or without N and/or O on the surfaces of the first via cavity 902a (or the first etched region 1202a) and the second via cavity 902b (or the second etched region 1202b) to thereby form the hydrogen-rich material layer (1102a, 1102b, 1302a, 1302b) that is contact with the surfaces of the active layer 602 and the gate dielectric layer 502. The method 1800 may further include depositing a conductive material over the hydrogen-rich material layer (1102a, 1102b, 1302a, 1302b) in the first via cavity 902a (or the first etched region 1202a) and the second via cavity 902b (or the second etched region 1202b) to thereby form the source electrode 1102 and the drain electrode 1104, respectively.

As described above, the method 1800 may include forming various embodiment transistor structures (1100, 1400) in a BEOL process over one of a plurality of metal interconnect level structures (such as the first metal interconnect structures (142, 144, 146, 148)) in an existing semiconductor structure (e.g., the semiconductor structure 100 of FIG. 1).

Referring to all drawings and according to various embodiments of the present disclosure, a transistor structure (1100, 1400) is provided. The transistor structure (1100, 1400) may include a gate electrode 402, an active layer 602, a gate dielectric layer 502 separating the active layer 602 from the gate electrode 402, a source electrode 1102, a drain electrode 1104; and a hydrogen-rich material layer (1102a, 1102b, 1302a, 1302b) separating the source electrode 1102 and the drain electrode 1104 from the active layer 602. In this regard, the first hydrogen-rich material layer (1002a, 1302a) separates the source electrode 1102 from the active layer 602, and the second hydrogen-rich material layer (1002b, 1302b) separates the drain electrode 1104 from the active layer 602. As described above, the transistor structure (1100, 1400) may be a thin-film transistor that may be formed in a BEOL process.

The active layer 602 may include a semiconducting material including, but not limited to, amorphous silicon, InGaZnO, InGaO, InWO, InZnO, InSnO, ZnO, GaO, InO, and alloys thereof. Other suitable materials are within the contemplated scope of disclosure. For example, in various embodiments, the oxide semiconductor layer 602L may include a composition given by Inx Gay Znz MO, wherein 0<x<1; 0≤y≤1; 0≤z≤1; and M is one of Ti, Al, Ag, Ce, and Sn.

The gate dielectric layer 502 may include a high-k dielectric material including one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina. In other embodiments, the gate dielectric layer 502 may include an alternating multi-layer structure including silicon oxide and silicon nitride. In still further embodiments, the gate dielectric layer 502 may include a ferroelectric material.

In various embodiments, the hydrogen-rich material layer (1102a, 1102b) may include TiN, WN, WCN Co, PdCo, Mo, etc., and alloys of W, Mo, Co, Pd, Ti, and mixtures thereof, with or without N and/or O, deposited by chemical vapor deposition or by atomic layer deposition.

Further embodiments include a transistor structure (1100, 1400) may be provided. The transistor structure (1100, 1400) may include a gate electrode 402, an active layer 602, a gate dielectric layer 502 separating the active layer 602 from the gate electrode 402, a source electrode 1102 and a drain electrode 1104, wherein each of the source electrode 1102 and the drain electrode 1104 include a hydrogen-rich fill material layer.

In one embodiment, the active layer may include one of amorphous silicon, InGaZnO, InGaO, InWO, InZnO, InSnO, ZnO, GaO, InO, InZnO, and alloys thereof. In one embodiment, the active layer may include a composition given by Inx Gay Znz MO, wherein 0<x<1; 0≤y≤1; 0≤z≤1; and M is one of Ti, Al, Ag, Ce, and Sn. In one embodiment, the gate dielectric layer comprises a high-k dielectric material may include one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina. In one embodiment, the transistor structure may also include a glue layer separating the source electrode from the active layer and separating the drain electrode from the active layer. In one embodiment, the transistor structure may also include a capping layer formed over the active layer. In one embodiment, the hydrogen-rich fill material may include TiN, WN, WCN Co, PdCo, Mo, etc., and alloys of W, Mo, Co, Pd, Ti, and mixtures thereof, with or without N and/or O, deposited by chemical vapor deposition or by atomic layer deposition.

Various disclosed transistor structures and methods of making the same provide advantages over existing transistor structures. In this regard, a transistor structure (1100, 1400) is provided that may be formed in a BEOL process and may be incorporated with other BEOL circuit components such as capacitors, inductors, resistors, and integrated passive devices. As such, the disclosed transistor structure (1100, 1400) may include materials that may be processed at low temperatures and thus, may not damage previously fabricated devices (e.g., FEOL and MEOL devices). The disclosed transistor structure (1100, 1400) may include a substrate 202 that may be formed in a BEOL process.

The disclosed transistor structures (1100, 1400) may further have improved device performance characteristics relative to existing BEOL compatible transistor structures. In this regard, existing compatible thin-film transistors often suffer degradation of the on-current due to high Schottky barrier heights respectively between the source electrode the active region, and between drain electrode and the active region. Metal contacts for source and drain electrodes of existing systems typically include pure metals (e.g., W, Cu, etc.) or materials deposited using PVD (TiN, W, etc.). Both such materials tend to have low amounts of hydrogen in the material and therefore often result in a high contact resistance and degraded device performance. Hydrogen is known to act has a donor-like dopant in oxide semiconductor materials used in thin-film transistors.

In contrast to existing BEOL compatible transistor structures, disclosed embodiment transistor structures (1100, 1400) include a hydrogen-rich material layer (1002a, 1002b, 1302a, 1302b) separating the source electrode 1102 from the active layer 602, and separating the drain electrode 1104 from the active layer 602. The presence of hydrogen in the hydrogen-rich material layer (1002a, 1002b, 1302a, 1302b) may reduce the contact resistance of the transistor structures (1100, 1400) and may act to reduce Schottky barriers respectively between the source electrode and the active layer, and between the drain electrode and the active layer, and may reduce contact resistances, thus leading to improved device performance.

The foregoing outlines features of several embodiments so that those skilled in the art may better understand the aspects of this disclosure. Those skilled in the art should appreciate that they may readily use this disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of this disclosure.

What is claimed is:

1. A transistor structure, comprising:
a gate electrode;
an active layer;
a gate dielectric layer separating the active layer from the gate electrode;
a source electrode and a drain electrode; and
a hydrogen-rich material layer separating the source electrode and the drain electrode from the active layer.

2. The transistor structure of claim 1, wherein the active layer comprises one of amorphous silicon, InGaZnO, InGaO, InWO, InZnO, InSnO, ZnO, GaO, InO, InZnO, and alloys thereof.

3. The transistor structure of claim 1, wherein the active layer comprises a composition given by InₓGa_{y}Zn_{z} MO, wherein 0<x<1; 0≤y≤1; 0≤z≤1; and M is one of Ti, Al, Ag, Ce, and Sn.

4. The transistor structure of claim 1, wherein the gate dielectric layer comprises a high-k dielectric material comprising one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina.

5. The transistor structure of claim 1, wherein the gate dielectric layer comprises an alternating multi-layer structure comprising silicon oxide and silicon nitride.

6. The transistor structure of claim 1, wherein the gate dielectric layer comprises a ferroelectric material.

7. The transistor structure of claim 1, wherein the hydrogen-rich material layer comprises TiN, WN, WCN Co, PdCo, Mo, etc., and alloys of W, Mo, Co, Pd, Ti, and mixtures thereof, with or without N and/or O, deposited by chemical vapor deposition or by atomic layer deposition.

8. A transistor structure, comprising:
a gate electrode;
an active layer;
a gate dielectric layer separating the active layer from the gate electrode;
a source electrode and a drain electrode, wherein each of the source electrode and the drain electrode comprise a hydrogen-rich fill material.

9. The transistor structure of claim 8, wherein the active layer comprises one of amorphous silicon, InGaZnO, InGaO, InWO, InZnO, InSnO, ZnO, GaO, InO, InZnO, and alloys thereof.

10. The transistor structure of claim 8, wherein the active layer comprises a composition given by InₓGa_{y}Zn_{z} MO, wherein 0<x<1; 0≤y≤1; 0≤z≤1; and M is one of Ti, Al, Ag, Ce, and Sn.

11. The transistor structure of claim 8, wherein the gate dielectric layer comprises a high-k dielectric material comprising one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina.

12. The transistor structure of claim 8, further comprising a glue layer separating the source electrode from the active layer and separating the drain electrode from the active layer.

13. The transistor structure of claim 8, further comprising a capping layer formed over the active layer.

14. The transistor structure of claim 8, wherein the hydrogen-rich fill material comprises one or more of TiN, WN, WCN Co, PdCo, Mo, and alloys of one or more of W, Mo, Co, Pd, Ti, and mixtures thereof, with or without N and/or O, deposited by chemical vapor deposition or by atomic layer deposition.

15. A method of fabricating a transistor structure, comprising:
forming a gate electrode;
forming an active layer;
forming a gate dielectric layer that is in contact with the gate electrode and the active layer and separating the gate electrode from the active layer;
forming a source electrode;
forming a drain electrode; and
forming a hydrogen-rich material layer separating the source electrode and the drain electrode from the active layer.

16. The method of claim 15, wherein forming the gate dielectric layer further comprises depositing a high-k dielectric material over the gate electrode,
wherein the high-k dielectric material comprising one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina.

17. The method of claim 15, wherein forming the gate dielectric layer further comprises:
forming an alternating multi-layer structure comprising silicon oxide and silicon nitride over the gate electrode; or
forming a ferroelectric material over the gate electrode.

18. The method of claim 15, wherein forming the active layer further comprises depositing one of amorphous silicon, InGaZnO, InGaO, InWO, InZnO, InSnO, ZnO, GaO, InO, InZnO, and alloys thereof over the gate dielectric layer.

19. The method of claim 15, wherein forming the source electrode, forming the drain electrode, and forming the hydrogen-rich material layer further comprises:
forming an inter-layer dielectric layer over the active layer;
etching the inter-layer dielectric layer to thereby generate a first via cavity and a second via cavity, wherein the first via cavity and the second via cavity each expose respective surfaces of the active layer;
performing a chemical vapor deposition process or an atomic layer deposition process to deposit one or more of TiN, WN, WCN Co, PdCo, Mo, and one or more of alloys of W, Mo, Co, Pd, Ti, and mixtures thereof, with or without N and/or O on the surfaces of the first via cavity and the second via cavity to thereby form the hydrogen-rich material layer that is contact with the surfaces of the active layer; and
depositing a conductive material over the hydrogen-rich material layer in the first via cavity and in the second via cavity to thereby form the source electrode and the drain electrode, respectively.

20. The method of claim 15, further comprising forming the transistor structure in a BEOL process over one of a plurality of metal interconnect level structures in an existing semiconductor structure.
